(19) United States
(12) Patent Application Publication
(10) Pub. No.: US 2008/0277766 A1
(43) Pub. Date: Nov. 13, 2008

(54) Polymer membranes for microcalorimeter devices

(76) Inventors: Robin Harold Cantor, Santa Fe, NM (US); John Addison Hall, Albuquerque, NM (US)

Correspondence Address: DUANE MORRIS LLP - Philadelphia;IP DEPARTMENT, 30 SOUTH 17TH STREET, PHILADELPHIA, PA, 19103-4196, US

(21) Appl. No.: 11/184,225

(22) Filed: Jul. 19, 2005

Related U.S. Application Data
(60) Provisional application No. 60/589,246, filed on Jul. 20, 2004.

(51) Int. Cl. H01L 23/58; H01L 21/311

(52) U.S. Cl. 257/643; 438/697; 257/E21.24

(57) ABSTRACT

An improved structure for supporting a microcalorimeter device is disclosed. The structure comprises a substrate with superconducting wiring elements disposed on a surface of the substrate. A membrane layer is suspended above the wiring elements and the substrate surface by a tab element, and a microcalorimeter is disposed on top of the membrane layer. The tab and the membrane layer reside in a common plane, and the membrane layer comprises a material that can be applied and cured at low temperatures (e.g. 350 degrees Celsius or less), so as to have minimal affect on the superconductive wiring elements. The in-plane tab/membrane structure has improved reliability when subject to thermal cycling associated with cryogenic temperatures. A method for forming the structure is also disclosed.

### CROSS-REFERENCE TO RELATED APPLICATIONS

This application claims priority to U.S. Provisional Application Ser. No. 60/589,246 filed Jul. 20, 2004 by Robin Cantor et al., the entire contents of which application is incorporated by reference herein.

### GOVERNMENT LICENSE RIGHTS

The U.S. Government has a paid-up license in this invention and the right in limited circumstances to require the patent owner to license others on reasonable terms as provided for by the terms of contract NNG04CA75C, awarded by NASA.

### FIELD OF THE INVENTION

The present invention generally relates to microcalorimeter devices and, more particularly, to the fabrication of microcalorimeters such as transition edge sensor (TES) detectors on thin membranes of polymer materials.

### BACKGROUND OF THE INVENTION

Surface micromachining techniques are known for fabricating transition edge sensor (TES) microcalorimeter detectors and detector arrays on deposited silicon nitride membranes. The membrane isolates the associated microcalorimeter detector by suspending the detector above the substrate/chip. The silicon nitride material used with such surface micromachining techniques, however, is typically deposited at high temperatures (e.g. 700-800 degrees Celsius), which can adversely affect the quality of the underlying wiring structures by degrading the superconductivity or the electrical or mechanical properties of the thin film wiring. Such high deposition temperatures can also eliminate the possibility of fabricating circuit elements of the readout electronics for the detectors on the same substrate (i.e. the same chip), which in turn limits the number of detectors that can be fabricated on a single chip.

Additionally, current surface micromachined membranes used to fabricate TES microcalorimeter detectors are typically supported by several legs oriented at roughly forty-five degree (45°) angles with respect to the substrate. These angled legs are susceptible to breakage as a result of thermal cycling at cryogenic temperatures.

There is a need in the art for improved microcalorimeter support/insulation structures, as well as an improved method for forming such structures. The resulting support structures should have robust geometries that will resist breakage caused by thermal cycling at cryogenic temperatures, and the technique for forming such structures should utilize materials that can be applied at low temperature so as to minimize thermal effects on the underlying superconductive wiring structures and circuit elements.

### SUMMARY OF THE INVENTION

The present invention provides a planarization and surface micromachining technique for the fabrication of microcalorimeters such as TES detectors on thin membranes of polymer films such as polyimide. Using a sacrificial layer and low-temperature planarization process, the micromachining technique enables the microcalorimeters to be suspended on a thin polymer membrane under which wiring for the microcalorimeters and circuit elements of the readout electronics can be located.

A method for forming a suspended polymer membrane is disclosed, comprising: providing a substrate; providing a wiring structure on a surface of said substrate; providing a first material layer over said surface of said substrate, said first material layer covering at least a portion of said wiring structure; providing a second material layer over a surface of said first material layer; defining a pathway through said second material layer to expose said surface of said first material layer; and forming a membrane from said second material layer by etching said first material layer through said pathway to remove at least a portion of said first material layer from beneath said second material layer; wherein said second material layer is capable of being cured at a temperature of less than about 350 degrees Celsius.

A method for forming a support for a microcalorimeter is disclosed, comprising: providing a substrate; providing a wiring structure in, or on a surface of, said substrate; providing a sacrificial polysilicon layer over said substrate and said wiring structure; patterning said sacrificial polysilicon layer to define a sacrificial island; providing a planarizing layer over said polysilicon layer; defining a channel through said planarizing layer to expose a surface of said sacrificial island; and etching away at least a portion of said sacrificial island by exposing said sacrificial island to etching chemicals introduced through said channel; wherein said etching step forms a void space between said planarizing layer and said substrate, thus suspending a membrane portion of said planarizing layer over said substrate.

A structure for supporting a microcalorimeter is disclosed, comprising a substrate having a surface; a superconductive wiring element associated with said surface; and a membrane layer disposed over said surface. A surface of the membrane layer may be spaced apart from the surface of the substrate by a distance, thus defining a space between said membrane layer and said surface. The membrane layer may be supported over the surface of the substrate by a tab element having a surface. The surface of the tab element may be coplanar with the surface of the membrane layer. The membrane layer may further comprise a material that can be applied and cured at a temperature of less than about 350 degrees Celsius.

### BRIEF DESCRIPTION OF THE DRAWINGS

These and other features and advantages of the present invention will be more fully disclosed in, or rendered obvious by, the following detailed description of the preferred embodiment of the invention, which is to be considered together with the accompanying drawings wherein like numbers refer to like parts and further wherein:

FIG. 1 is a cross-section view showing a structure comprising a substrate having a wiring layer and a layer of polysilicon;

FIG. 2 is a cross-section view showing a layer of polymer disposed over the layer of polysilicon, with etching holes defined through the polymer layer;

FIG. 3 is a cross-section view of the structure of FIG. 2 subsequent to etching, with the silicon layer removed;

FIG. 4 is a top plan view of the structure of FIG. 3.

### DETAILED DESCRIPTION

This description of preferred embodiments is intended to be read in connection with the accompanying drawings, which are to be considered part of the entire written description of this invention. The drawing figures are not necessarily to scale and certain features of the invention may be shown exaggerated in scale or in somewhat schematic form in the interest of clarity and conciseness. In the description, relative terms such as “horizontal,” “vertical,” “up,” “down,” “top” and “bottom” as well as derivatives thereof (e.g., “horizontally,” “downwardly,” “upwardly,” etc.) should be construed to refer to the orientation as then described or as shown in the drawing figure under discussion. These relative terms are for convenience of description and normally are not intended to require a particular orientation. Terms including “inwardly” versus “outwardly,” “longitudinal” versus “lateral” and the like are to be interpreted relative to one another or relative to an axis of elongation, or an axis or center of rotation, as appropriate. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise. The term “operatively connected” is such an attachment, coupling or connection that allows the pertinent structures to operate as intended by virtue of that relationship.

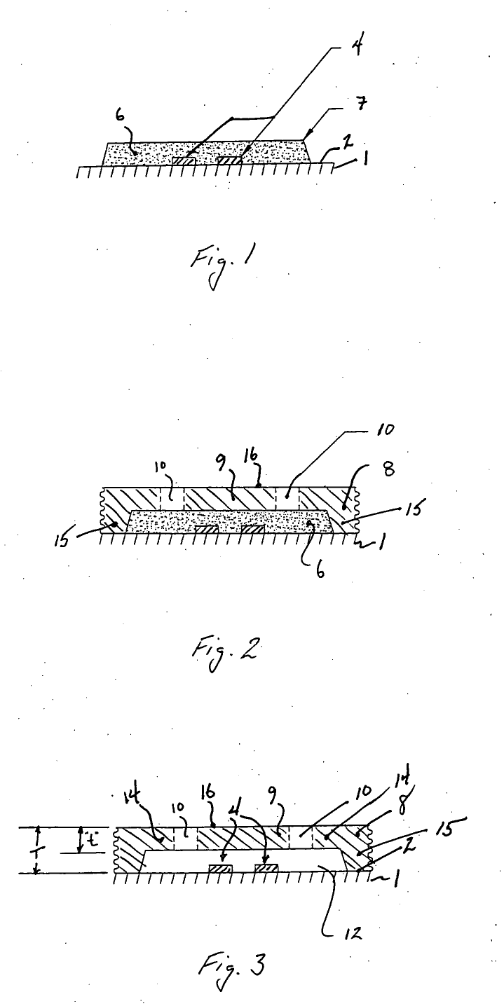

Referring to FIGS. 1 and 2, a substrate 1, such as a silicon wafer, may have a surface 2 upon which one or more wiring elements 4 are formed. These wiring elements 4 may include detector wiring and/or circuit elements of readout electronics associated with a microcalorimeter device (not shown). A sacrificial layer 6 may be disposed above the substrate 1 and wiring elements 4. The sacrificial layer 6 may be patterned to form one or more sacrificial islands 7. A support layer 8 may be disposed over the sacrificial island 7, and a microcalorimeter device (not shown) may be fabricated on the support layer 8 so that it overlies the sacrificial island 7. Contact vias (not shown) may be formed through the support layer 8 to provide interconnects (not shown) between the wiring elements 4 and the microcalorimeter device. The sacrificial island 7 may then be etched from beneath the support layer 8 by allowing an etchant material to react with the material of the sacrificial island 7 through one or more etch channels 10 formed through the support layer 8. A void space 12 is thus created between the substrate 1 and the support layer 8, defining a free-standing membrane portion 9 of the support layer 8. It is upon this free-standing membrane portion 9 that the microcalorimeter device is suspended. The membrane portion 9 may be connected to the support layer 8 by at least one tab element 14 (FIG. 4). The tab element 14 may be connected to the substrate by a footing portion 15. The sacrificial islands 7 typically have a sloped edge profile following the patterning of the islands using standard photolithographic and wet or dry chemical etch processes, which is desirable for improved mechanical robustness but not essential.

It will be appreciated that although the arrangement of FIGS. 1-4 show the structure of a single microcalorimeter support, the principles of formation illustrated and described may be extrapolated to the fabrication of a plurality of supports (and associated microcalorimeter devices) on a single substrate chip, thus facilitating the fabrication of closely-packed microcalorimeter detector arrays.

Referring again to FIG. 1, the substrate 1 can be a semiconductor wafer made of any of a variety of appropriate semiconductor materials, including silicon, germanium, and the like. The wiring elements 4 can be made from niobium or other. appropriate superconductive wiring. The sacrificial layer 6 may be an appropriate poly-silicon, which may be bias sputtered onto the top surface of the substrate 1. Bias sputtering is a well-known technique for depositing planarized materials over thin-film structures. Using poly-silicon as the sacrificial island 7 may be advantageous because it exhibits a high etch rate and high selectivity to certain etchant gases, such as Xenon difluoride (XeF₂), which may ensure that the etching process will adequately remove the sacrificial island 7 while not substantially affecting the substrate 1 or the overlying support layer 8. It will be appreciated that etchant gases such as XeF₂ may also slightly attack the materials (e.g. Niobium) used for the wiring elements 4, and thus, a suitable encapsulation layer such as silicon dioxide (SiO₂) or silicon nitride (Si₃N₄) may be provided between the wiring elements 4 and the sacrificial island 7 to protect the wiring elements 4.

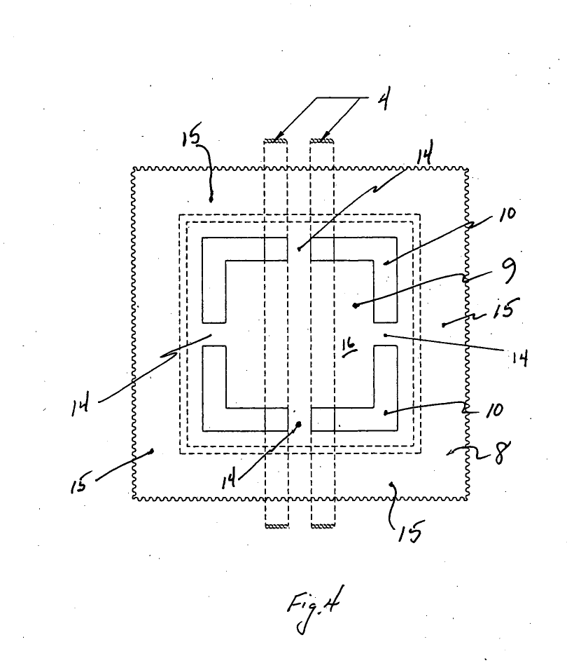

In one exemplary embodiment, the support layer 8 may be formed from a photosensitive polyimide that can be cured at low temperatures (e.g. at about 150 degrees Celsius). One example of such a photosensitive polyimide is a multi-block polyimide with a photosensitive diazonaphtoguinone (DNQ) compound. Spin coating this photosensitive polyimide by applying two or more coats can be used to build up a layer thickness of a few microns. Thicknesses in the range of typically 1 um to 5 um are desirable to ensure mechanical stability. The use of a photosensitive polyimide enables the support layer 8 to be easily patterned using conventional photolithography techniques to open contact vias (not shown) which may be used to connect the underlying wiring elements 4 to the microcalorimeter device, and to create the aforementioned tab elements 14 and footing portions 15 (see FIGS. 3 and 4) that will ultimately support the membrane portion 9 of the support layer 8 after the sacrificial layer 6 is etched away. It has already been demonstrated that this polyimide material is suitable for use as a dielectric film for the fabrication of low-temperature dc Superconducting Quantum Interference Devices (SQUIDs). See Katsuya Kikuchi, Shigemasa Segawa, Eun-Sil lung, Hiroshi Nakagawa, Kazuhiko Tokoro, Hiroshi Itatani, and Masahiro Aoyagi, IEEE Trans. Appl. Superconductivity 13, 119 (2003), the entire contents of which is incorporated by reference herein.

In a second exemplary embodiment the support layer 6 can be formed from a low-stress, non-photosensitive polyimide material, such as SRS 7503 polyimide based on THF and DMAc solvent systems available from SRS Technologies or PIQ 2610 polyimide from HD Microsystems. This material may be applied in a single coat to a thickness of about 1 to 3 μm. Such non-photosensitive polyimide materials require a slightly higher cure temperature than the photosensitive polyimide materials (e.g. 150° C. to 350° C.), and because the material is not photosensitive it may not be directly patterned. To pattern the low-stress, non-photosensitive polyimide material, a standard photoresist mask and dry etch process may be used. The slightly higher cure temperature of this material is not expected to adversely affect the underlying wiring elements 4 on the substrate 1.

As an alternative to the polyimide materials, the support layer 6 may comprise a polymer based on polyhydroxide styrene in the form of a negative photoresist with a post patterning silylation process. As a negative resist, this material may easily be patterned, thus incorporating one advantage of the photosensitive polyimide films. Additionally, the post patterning silylation process is expected to offer improved structural ruggedness, due to the implantation of silicon rich molecules in the top layers of the photoresist. The negative resist of this embodiment offers the additional advantage that it may be applied by spin coating using standard equipment, as opposed to conventional polyimide materials that may require a dedicated spinner. Following application, this negative resist may be soft baked, then patterned using an appropriate exposure and development technique. The patterned resist may then be bleached using ultraviolet (UV) light and then hard baked at about 125 degrees Celsius for about seventy (70) minutes. For the stabilizing silylation process, the patterned negative resist may be exposed to 2,2,4,4,6,6-hexamethyl-cyclotrisilazane (HMCTS) in a vacuum oven set at about 145 degrees Celsius for about seventy (70) minutes. The same oven used for hexamethyidisilazane (HMDS) wafer priming—a process that may be used to prepare the substrate 1 to receive the support layer 6—may be used for this purpose.

Advantageously, each of these noted films used for the support layer 6 serve to planarize the substrate 6 and wiring structure 4 so that the membrane portion 9 and supporting tabs 14 will be in-plane and therefore may be less sensitive to damage resulting from the aforementioned thermal cycling and handling. This is a distinct advantage over current tabs which as previously noted are oriented at an angle with respect to the membrane and thus are susceptible to damage due to thermal cycling.

Referring again to FIGS. 1-4, an exemplary membrane portion 9 may be fabricated as follows. A sacrificial layer 6 comprising a suitable poly-silicon composition may be deposited (e.g., using bias sputtering) over a pre-patterned substrate 1 having Niobium wiring elements 4 and other circuit elements (not shown) as desired. The sacrificial layer 6 may then be patterned to define an array of sacrificial islands 7 (see FIG. 1). The free-standing membrane portions 9 will be formed above these sacrificial islands 7. In one embodiment, one membrane portion 9 will be formed above each sacrificial island 7. The substrate 1 (with wiring elements 4 and patterned sacrificial islands 7) may then be planarized by spin coating to form a support layer 8 comprising one of the polyimide materials or polyhydroxide styrene material previously described. The support layer 8 may then be cured, again using the process appropriate for the particular support layer material utilized. Etch windows 10 may then be patterned or otherwise formed through the support layer 8 to expose a portion of the underlying sacrificial island 7 which was formed from sacrificial layer 6. Where a photosensitive material is used for the support layer 8, the material may be patterned as described above. Where a non-photosensitive material is used for the support layer 8, the material may be patterned using an appropriate resist stencil and etch.

The microcalorimeter device (not shown) may then be formed on an upper surface 16 of the support layer 8 in a location overlying a prospective membrane portion 9 (i.e. overlying an associated sacrificial island 7). Contact vias (not shown) may then be formed through the support layer 8 at appropriate locations (e.g. through the footing portions 15) using an isotropic etch followed by depositing conductive material within the contact vias to form interconnects between the underlying wiring elements 4 and the microcalorimeters formed on top of the support layer 8. It is noted that the contact vias may be formed using an isotropic etch to obtain suitably sloped edges to ensure good coverage on the sidewalls of the vias and a bias sputtering technique for the top wiring deposition. Filling the contact vias can be performed simultaneous with, or separate from, forming the top wiring elements. The space around each pixel for the membrane footings and contact vias can be minimized using this technique for the contact vias and interconnecting wiring, which is important for the fabrication of close-packed arrays.

After the microcalorimeter and associated interconnects have been formed, the underlying sacrificial island 7 may be etched away using a gas etch process, leaving the microcalorimeter supported by a free-standing membrane portion 9. The membrane portion 9 itself may be supported by one or more support tab elements 14 and footing portions 15. In a preferred embodiment, the sacrificial island 7 is formed from a poly-silicon material, and XeF₂ gas is used as the etchant. The poly-silicon material of the sacrificial island 7 is extremely reactive to the XeF₂ gas atmosphere, and thus an exposure to the gas through the etch windows 10 causes the gas to react with the poly-silicon of the sacrificial island 7, forming a volatile material which may be pumped away. The etching process may be performed in a series of steps, or pulses, in which the XeF₂ gas is bled in, exposure occurs, followed by the XeF₂ gas and volatile materials being pumped out. This process may be repeated until a visual observation of the membrane portion 9 reveals that the sacrificial island 7 has been substantially removed. This may be determined by observing the color of the membrane portion 9, which may change appreciably when the sacrificial island 7 has been substantially removed. The membrane portion 9 may have a resulting thickness of about one micron to about five microns, although other thicknesses are possible.

The etch openings will also serve to form the support tab elements 14. Thus, FIG. 4 shows the etch windows 10 as each having an L-shape, which forms four supporting tabs 14. It will be appreciated that other shapes may also be appropriate for the etch windows 10, and that careful control of shape or shapes of the etch windows 10 can be achieve a desired shape of the supporting tab 14, which may result in supporting tabs 14 having desired predetermined strength characteristics.

As can be seen, using the planarization technique of the present invention, the supporting tabs 14 are substantially flat and reside in the same plane as the associated membrane portion 9. Additionally, the footing portions 15 that run from each supporting tab 14 to the substrate are continuous around the perimeter of the membrane portion 9 and have a thickness “T” (FIG. 3) that is greater than the thickness “t” of the supporting tabs 14, thus improving the robustness of the structure over the known angled tab structures. The thickness “t” of the supporting tabs 14 may be from about 1μ to about 3μ, though other thicknesses may also be appropriate.

Furthermore, given the highly amorphous nature of the polymer films used to form the support layer 8 and membrane portion 9, the thermal conductivity of polymer is expected to be lower than that for silicon nitride, which has been used previously for microcalorimeter membranes. This means that a membrane made from the materials described may be made thicker, or the supporting tabs could be made wider, without compromising detector performance, which may help further improve the structural robustness of the membrane portion 9. Since the thermal conductivity also depends on the size of the microcalorimeter detector fabricated on top of the membrane portion 9, the dimensions (length, width) of the supporting tabs 14 can be adjusted for a given thickness of the membrane portion 9 and particular microcalorimeter design to tune the thermal conductivity to the desired target value, typically of the order of 0.5 nano-Watts per degree Kelvin (nW/K) at 0.1 K.

Furthermore, using a low-temperature (e.g. <150° C.) cure for the support layer 8 enables integration of the superconducting wiring elements 4 for the individual microcalorimeter detectors and circuit elements of the readout electronics, which may be SQUIDs, to be integrated on the same substrate 1. The inventive planarization and surface micromachining technique also improves the robustness of the overall structure. Additionally, integrating the detector wiring elements 4 and elements of the readout electronics beneath the microcalorimeter may simplify the fabrication of closely-packed microcalorimeter detector arrays.

It is to be understood that the present invention is by no means limited only to the particular constructions herein disclosed and shown in the drawings, but also comprises any modifications or equivalents within the scope of the claims.

What is claimed is:

1. A method for forming a suspended polymer membrane, comprising:
providing a substrate;
providing a wiring structure on a surface of said substrate;
providing a first material layer over said surface of said substrate, said first material layer covering at least a portion of said wiring structure;
providing a second material layer over a surface of said first material layer;
defining a pathway through said second material layer to expose said surface of said first material layer; and
forming a membrane from said second material layer by etching said first material layer through said pathway to remove at least a portion of said first material layer from beneath said second material layer;
wherein said second material layer is capable of being cured at a temperature of less than about 350 degrees Celsius.

2. The method of claim 1, further comprising providing a microcalorimeter detector device above a surface of said second material layer; and forming interconnect structures through said second material layer to connect said microcalorimeter detector device to said wiring structure.

3. The method of claim 2, wherein said first material layer comprises poly-silicon, and said step of etching said first material layer comprises a gas etch using Xenon difluoride (XeF₂) gas.

4. The method of claim 3, wherein said second material layer comprises a polyimide material having a curing temperature of about 250 degrees Celsius or less.

5. The method of claim 3, wherein said second material layer comprises a polyhydroxide styrene material having a curing temperature of about 145 degrees Celsius or less.

6. The method of claim 1, wherein said membrane is connected to said second material layer via a tab portion, said tab portion having a surface that is coplanar with a surface of said membrane.

7. The method of claim 1, wherein said wiring structure comprises superconductive wiring.

8. A method for forming a support for a microcalorimeter, comprising:
providing a substrate;
providing a wiring structure in, or on a surface of, said substrate;
providing a sacrificial polysilicon layer over said substrate and said wiring structure;
patterning said sacrificial polysilicon layer to define a sacrificial island;
providing a planarizing layer over said polysilicon layer;
defining a channel through said planarizing layer to expose a surface of said sacrificial island; and
etching away at least a portion of said sacrificial island by exposing said sacrificial island to etching chemicals introduced through said channel;
wherein said etching step forms a void space between said planarizing layer and said substrate, thus suspending a membrane portion of said planarizing layer over said substrate.

9. The method of claim 9, further comprising the step of forming a microcalorimeter device on a surface of said planarizing layer, said microcalorimeter device being supported above said substrate by said membrane portion.

10. The method of claim 9, further comprising the step of forming an interconnect structure through said planarizing layer to electrically connect said wiring structure to said microcalorimeter device.

11. The method of claim 9, wherein said step of etching comprises etching with XeF₂ gas.

12. The method of claim 9, wherein said wiring structure comprises a superconductive material.

13. The method of claim 9, wherein said planarizing layer comprises a polyimide material having a curing temperature of about 350 degrees Celsius or less.

14. The method of claim 9, wherein said planarizing layer comprises polyhydroxide styrene.

15. A structure for supporting a microcalorimeter, comprising:
a substrate having a surface;
a superconductive wiring element associated with said surface; and
a membrane layer disposed over said surface, a surface of said membrane layer being spaced apart from said surface by a distance thus defining a space between said membrane layer and said surface;
wherein said membrane layer is supported over said surface of said substrate by a tab element having a surface, said surface of said tab element being coplanar with said surface of said membrane layer, the membrane layer further comprising a material that can be applied and cured at a temperature of less than about 350 degrees Celsius.

16. The structure of claim 15, further comprising a microcalorimeter device disposed above said surface of said membrane layer, said microcalorimeter device being electrically connected to said superconductive wiring element.

17. The structure of claim 15, wherein said planarizing layer comprises a polyimide material.

18. The structure of claim 15, wherein said material comprises a polyhydroxide styrene material that can be applied and cured at a temperature of about 125 degrees Celsius or less.

19. The structure of claim 15, wherein said tab element has first and second ends, said first end being connected to said membrane layer, and said second end being connected to a support element, said support element being connected to said substrate.

20. The structure of claim 19, comprising a plurality of tab elements each having first and second ends, said first end of each said tab element being connected to said membrane layer, and said second end of each said tab element being connected to said support element.
